(19) United States
(12) Patent Application Publication
(10) Pub. No.: US 2026/0136635 A1
(43) Pub. Date: May 14, 2026

(54) POWER SEMICONDUCTOR MODULE WITH EXTERNAL CONACT AREAS

(71) Applicant: Semikron Danfoss Elektronik GmbH & Co. KG, Nürnberg (DE)

(72) Inventor: Andreas WOHLFART, Nürnberg (DE)

(21) Appl. No.: 19/385,660

(22) Filed: Nov. 11, 2025

(30) Foreign Application Priority Data
Nov. 13, 2024 (DE) 102024133184.4

(51) Int. Cl. H10D 80/20; H01L 21/48; H01L 21/56; H01L 23/31; H01L 23/498; H01L 25/00; H01L 25/07

(52) U.S. Cl. CPC H10D 80/20; H10W 70/093; H10W 70/658; H10W 74/016; H10W 74/114; H10W 90/00; H10W 90/701

(57) ABSTRACT

The following is presented: A power semiconductor module with a substrate, having a substrate support, a plurality of conductor tracks arranged thereon and a power semiconductor component that is arranged on one of these conductor tracks and is connected internally in a circuit-compatible manner, with an electrically conductive flat intermediate element, the first surface of which, facing the substrate, is connected in an electrically conductive manner to a contact area of the substrate, with a contact element for the external connection of the substrate, wherein the contact element is arranged completely within the substrate and the first surface thereof, facing the substrate, is connected in an electrically conductive manner to the second surface of the intermediate element, which lies opposite the first, wherein the contact element overlaps the assigned intermediate element laterally on one side, with a casting compound that covers the substrate and leaves a portion of the second surface of the contact element, which lies opposite the first, free. An associated method for manufacturing this power semiconductor module is also presented.

### CROSS-REFERENCE TO RELATED APPLICATION

This application claims foreign priority benefits under 35 U.S.C. § 119 from German Patent Application No. 102024133184.4, filed Nov. 13, 2024, the contents of which are hereby incorporated by reference in their entirety.

### TECHNICAL FIELD

The invention describes a power semiconductor module with a substrate, having a substrate support, a plurality of conductor tracks arranged thereon and a power semiconductor component that is arranged on one of these conductor tracks and is connected internally in a circuit-compatible manner, with an electrically conductive flat contact element as an external load terminal of the power semiconductor module.

Furthermore, the invention describes a method for manufacturing such a power semiconductor module.

### BACKGROUND

DE 10 2005 061 772 A1 discloses a power semiconductor module with at least one support plate that has a first metal layer on a first side, which first metal layer faces outwards and forms part of the outer side of the power semiconductor module, and has a second metal layer on a second side, which second metal layer is oriented inwards and is secured to the at least one power semiconductor component, and with a plastic body made of a thermosetting plastic, which encloses the support plate with the exception of the first metal layer or at least a part thereof. It is desirable to ensure that the semiconductor components are cooled satisfactorily and have a sufficient service life. For this purpose, it is envisaged that the plastic has a coefficient of thermal expansion that corresponds to that of the support plate.

### SUMMARY

In the knowledge of the prior art, the invention is based on the object of specifying a cast power semiconductor module and a method for the manufacture thereof, which method permits a compact construction, in particular with a small footprint.

This object is achieved according to the invention by a power semiconductor module, preferably without a frame-like housing or any other housing, in particular a plastic housing, with a substrate, having a substrate support, a plurality of conductor tracks arranged thereon and a power semiconductor component that is arranged on one of these conductor tracks and is connected internally in a circuit-compatible manner, with an electrically conductive flat intermediate element, the first surface of which, facing the substrate, is connected in an electrically conductive manner to a contact area of the substrate, with a contact element for the external connection of the substrate, wherein the contact element is arranged completely within the substrate and the first surface thereof, facing the substrate, is connected in an electrically conductive manner to the second surface of the intermediate element, which lies opposite the first, wherein the contact element overlaps the assigned intermediate element laterally on one side, with a casting compound, in particular made of a thermosetting plastic, also referred to as a transfer moulding compound, that covers the substrate and leaves a portion of the second surface of the contact element, which lies opposite the first, free.

The contact element being arranged completely within the substrate should be understood to mean that the arrangement region of the contact element is limited to the region of the substrate, and the contact element is therefore arranged such that it does not protrude laterally beyond the surface of the substrate in the viewing direction towards said surface.

It may be advantageous if the contact area of the substrate is formed as a load terminal area of the power semiconductor component. It may also be advantageous if the contact area of the substrate is formed as a portion of a conductor track.

It may be preferred if the surface area of the second surface of the intermediate element is smaller than the surface area of the first surface of the contact element.

It may be advantageous if a thickness of the intermediate element is greater than a thickness of the contact element. In particular, a plurality of intermediate elements may have different thicknesses.

Furthermore, it may be preferred if a contact element is electrically conductively connected to a plurality of intermediate elements.

The object is furthermore achieved by a method for manufacturing a power semiconductor module according to the invention, having the following steps:
a. providing a substrate support that has a plurality of conductor tracks arranged thereon;
b. arranging and materially bonding a power semiconductor component on a conductor track;
c. arranging and materially bonding an intermediate element on a conductor track or on a load terminal area of the power semiconductor component;
d. arranging and materially bonding the contact element on the intermediate element, wherein the contact element overlaps the assigned intermediate element laterally on one side;
e. casting the substrate in such a way that a portion of the second surface of the contact element remains free and thus accessible from outside.

It may be advantageous if steps b) and c) are performed simultaneously and the intermediate element is arranged on a conductor track.

It may be preferred if, in step c), the material bonding of the intermediate element to the conductor track is performed as an adhesive bonding, a soldered bonding, a welded bonding or a sintered bonding. It may also be preferred if, in step c), the material bonding of the intermediate element to the power semiconductor component is performed as an adhesive bonding, a soldered bonding or a sintered bonding.

It may be advantageous if, in step d), the material bonding of the contact element to the intermediate element is performed as an adhesive bonding, a soldered bonding, a welded bonding or a sintered bonding.

In principle, it may be advantageous if, prior to method step d), a module-internal connecting device is arranged or designed to form the circuit-compatible connection of the power semiconductor component.

Of course, unless explicitly or inherently excluded, or contrary to the concept of the invention, the features mentioned in the singular, such as the intermediate element and the contact element, may also be present multiple times in the power semiconductor component according to the invention or be implemented in the manufacturing method. [0017] It will be understood that the various configurations of the invention can be realized individually or in any desired combination to achieve improvements, irrespective of whether this is in the context of the power semiconductor module or of the manufacturing method. In particular, the features mentioned and explained above and below can be used not only in the specified combinations but also in other combinations or in isolation, without departing from the scope of the present invention.

### BRIEF DESCRIPTION OF THE DRAWINGS

Further explanations of the invention, advantageous details and features can be gathered from the following description of the exemplary embodiments of the invention, or of respective parts thereof, which are depicted schematically in FIGS. 1 to 10.

FIGS. 1, 3 and 5 show various stages of the method according to the invention for manufacturing a first configuration of a power semiconductor module according to the invention in a plan view.

FIGS. 2, 4 and 6 show the respective various stages in a lateral view.

FIGS. 7 and 8 show a second configuration of a power semiconductor module according to the invention as an alternative to FIGS. 5 and 6.

FIGS. 9 and 10 show a third configuration of a power semiconductor module according to the invention as an alternative to FIG. 3.

### DETAILED DESCRIPTION

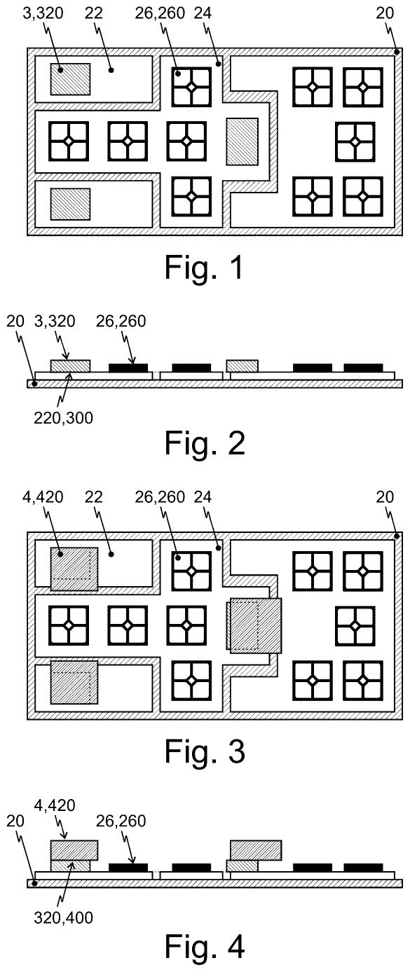

FIGS. 1, 3 and 5 show various stages of the method according to the invention for manufacturing a first configuration of a power semiconductor module 1 according to the invention in a plan view. FIGS. 2, 4 and 6 show the respective various stages in a lateral view. A power semiconductor module 1 according to method step c) is depicted in FIGS. 1 and 2. At this point in time, said power semiconductor module 1 has a substrate 2 with a substrate support 20, formed as a customary ceramic substrate support purely by way of example. A plurality of conductor tracks 22, 24, formed as copper conductor tracks here, are arranged on this substrate support 20.

In each case, a plurality of power semiconductor components 26 are arranged on two of these conductor tracks 24, which power semiconductor components 26 here in each case form a switch of a power-electronic circuit arrangement, here a half-bridge arrangement. On the side of the power semiconductor component 26 facing away from the substrate support 20, said power semiconductor component 26 has a contact area 260 that, in this configuration, is not connected to an intermediate element.

Here, purely by way of example, contact areas 220 are formed on three conductor tracks 22, 24, which contact areas 220 are intended to be electrically conductively connected to an intermediate element in a materially-bonded manner, by means of a customary configuration. The intermediate elements 3 arranged on these contact areas are themselves formed as flat metal bodies here, made of copper by way of example and, in this configuration, have a thickness that corresponds to 2 to 5 times the thickness of a power semiconductor component 26.

FIGS. 3 and 4 show the power semiconductor module 1 according to method step d). An assigned contact element 4 is arranged on each of the intermediate elements 3 and electrically conductively connected thereto in a materially-bonded manner, by means of a customary configuration. The respective contact element 4 is arranged completely within the substrate 2. The contact element 4 therefore does not protrude laterally beyond the edge regions, depicted as a dashed line here, of the substrate 2. A first surface 400 of the contact element 4, facing the substrate 2, is partially electrically conductively connected to the second surface 320 of the intermediate element 3, which lies opposite the first, specifically to the intermediate element 3 in the overlapping region.

In this configuration, these contact elements 4 have a thickness that is 30% to 60% greater than the thickness of the assigned intermediate element. It is particularly preferable, regardless of the above in principle, if the thickness of the contact element 4 is a multiple of, in particular three to five times, the thickness of the conductor track 22, 24. Above all, it is essential that each contact element 4 overlaps the assigned intermediate element 3 laterally on at least one side, therefore parallel to the substrate support 20, in the viewing direction towards said substrate support 20.

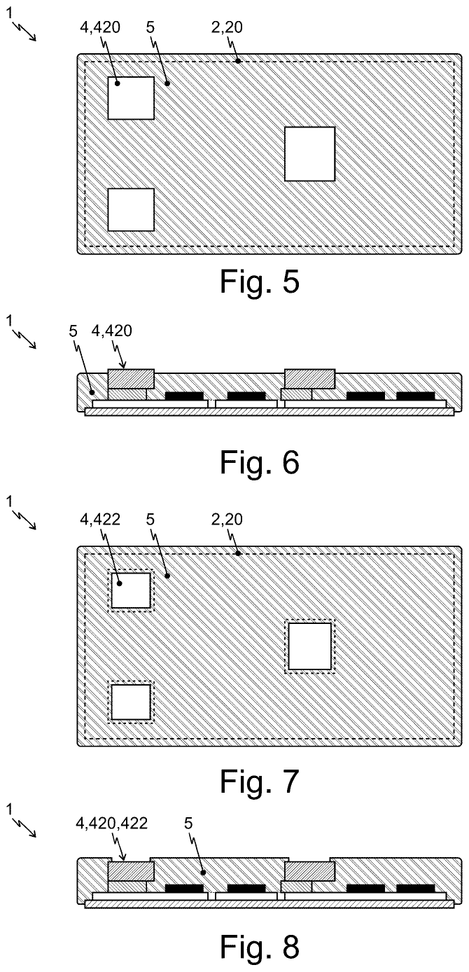

FIGS. 5 and 6 show the power semiconductor module 1 according to method step e). In this method step, the substrate 2 was cast by means of a transfer moulding method. In this configuration, the contact elements 4 partially stand out from the surface of the casting compound 5 parallel to the substrate support 20. Therefore, the entire second surface 420 of the contact elements 4 is accessible from outside and can be connected to external connection elements. The contact elements 4 are arranged completely within the substrate 2 here as well, shown by the dashed line, above the conductor tracks. This connection can be performed in a customary manner in particular as an adhesive bonding, a soldered bonding, a welded bonding or a sintered bonding.

FIGS. 7 and 8 show a second configuration of a power semiconductor module 1 according to the invention as an alternative to FIGS. 5 and 6, wherein the surface of the casting compound parallel to the substrate support 20 protrudes vertically beyond the respective second surface 420 of the contact elements 4, although a respective portion 422 of this second surface 420 remains free and thus accessible for an external connection.

What is advantageous with both of the mentioned configurations of the power semiconductor modules 1 firstly is that the portion 422 that is accessible from outside, regardless of whether it corresponds to the entire second surface 420 or only a part thereof, has a surface area that is greater than the assigned surface area of the contact area 220, 260 of the substrate 2. Secondly, it is advantageous that the significantly greater thickness of the contact element 4, compared to the conductor track with its contact area 220 or to the power semiconductor component with its contact area 260, makes the contact element 4 more robust against mechanical stress in the process of connecting an external connection element.

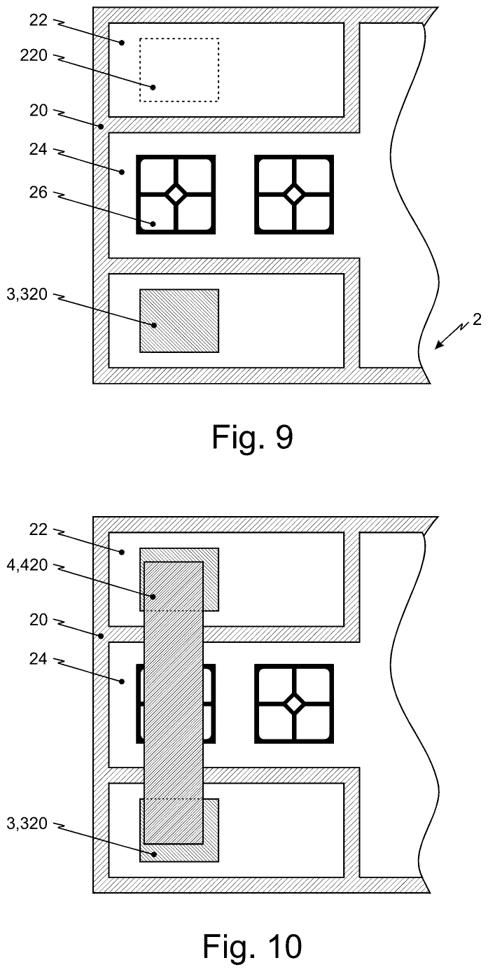

FIGS. 9 and 10 show a third configuration of a power semiconductor module 1 according to the invention as an alternative to the configuration according to FIG. 3. Here, FIG. 9 shows an enlarged detail of the substrate 2 analogous to FIG. 1, but with only one arranged intermediate element 3. FIG. 10 shows a contact element 4 within the substrate 2, which is connected to two intermediate elements 3.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed:

1. A power semiconductor module with a substrate, having a substrate support, a plurality of conductor tracks arranged thereon and a power semiconductor component that is arranged on one of these conductor tracks and is connected internally in a circuit-compatible manner, with an electrically conductive flat intermediate element, the first surface of which, facing the substrate, is connected in an electrically conductive manner to a contact area of the substrate, with a contact element for the external connection of the substrate, wherein the contact element is arranged completely within the substrate and the first surface thereof, facing the substrate, is connected in an electrically conductive manner to the second surface of the intermediate element, which lies opposite the first, wherein the contact element overlaps the assigned intermediate element laterally on one side, with a casting compound that covers the substrate and leaves a portion of the second surface of the contact element, which lies opposite the first, free.

2. The power semiconductor module according to claim 1, wherein
the contact area of the substrate is formed as a load terminal area of the power semiconductor component.

3. The power semiconductor module according to claim 1, wherein
the contact area of the substrate is formed as a portion of a conductor track.

4. The power semiconductor module according to claim 1, wherein
the surface area of the second surface of the intermediate element is smaller than the surface area of the first surface of the contact element.

5. The power semiconductor module according to claim 1, wherein
a thickness of the intermediate element is greater than a thickness of the contact element.

6. The power semiconductor module according to claim 1, wherein
a contact element is electrically conductively connected to a plurality of intermediate elements.

7. A method for manufacturing a power semiconductor module according to claim 1, having the following steps:
a. providing a substrate support that has a plurality of conductor tracks arranged thereon;
b. arranging and materially bonding a power semiconductor component on a conductor track;
c. arranging and materially bonding an intermediate element on a conductor track or on a load terminal area of the power semiconductor component;
d. arranging and materially bonding the contact element on the intermediate element, wherein the contact element overlaps the assigned intermediate element laterally on one side;
e. casting the substrate in such a way that a portion of the second surface of the contact element remains free and thus accessible from outside.

8. The method according to claim 7, wherein steps b) and c) are performed simultaneously and the intermediate element is arranged on a conductor track.

9. The method according to claim 7, wherein in step c), the material bonding of the intermediate element to the conductor track is performed as an adhesive bonding, a soldered bonding, a welded bonding or a sintered bonding.

10. The method according to claim 7, wherein in step c), the material bonding of the intermediate element to the power semiconductor component is performed as an adhesive bonding, a soldered bonding or a sintered bonding.

11. The method according to one claim 7, wherein in step d), the material bonding of the contact element to the intermediate element is performed as an adhesive bonding, a soldered bonding, a welded bonding or a sintered bonding.

12. The method according to claim 7, wherein prior to method step d), a module-internal connecting device is arranged or designed to form the circuit-compatible connection of the power semiconductor component.
